(19) United States
(12) Patent Application Publication
(10) Pub. No.: US 2025/0372468 A1
(43) Pub. Date: Dec. 4, 2025

(54) METHOD FOR PREPARING THREE-DIMENSIONAL STACKED OPTOELETRONIC PACKAGING STRUCTURE

(71) Applicant: SJ Semiconductor(Jiangyin) Corporation, Jiangyin City (CN)

(72) Inventors: Yenheng CHEN, Jiangyin City (CN); Chengchung LIN, Jiangyin City (CN)

(73) Assignee: SJ Semiconductor(Jiangyin) Corporation, Jiangyin City, JS (CN)

(21) Appl. No.: 18/842,786

(22) PCT Filed: Jun. 8, 2023
(86) PCT No.: PCT/CN2023/099213

§ 371 Date: Aug. 29, 2024

(30) Foreign Application Priority Data
Dec. 6, 2022 (CN) 202211553133.2

(51) Int. Cl. H01L 23/31; H01L 23/42; H01L 25/16

(52) U.S. Cl. CPC H01L 23/3121; H01L 23/42; H01L 25/167

(57) ABSTRACT

A method for preparing a three-dimensional stacked optoelectronic packaging structure. By utilizing a three-dimensional stacked mixed fan-out packaging, it effectively shortens the transmission path of photonic and electronic chips, enhances performance, and reduces package size. This allows for high-density integration and packaging of photonic and electronic chips with different process nodes through subsequent processes, while also addressing the thermal dissipation requirements of the optoelectronic packaging structure.

### FIELD OF TECHNOLOGY

The present disclosure belongs to the field of semiconductor packaging technology, in particular, it relates to a method for preparing a three-dimensional stacked optoelectronic packaging structure.

### BACKGROUND

Photonic device technologies offer advantages such as low signal attenuation, low energy consumption, high bandwidth, and CMOS process compatibility, all of which directly impact I/O bandwidth and energy consumption of the devices. Therefore, incorporating photonics technology with silicon CMOS process is essential in enhancing I/O bandwidth and minimizing energy consumption. In this context, the integration of photonics and silicon CMOS integrated circuits is crucial. Nevertheless, finding an effective way to combine and package photonic integrated circuits (PICs) with silicon electronic integrated circuits (EICs) has remained a pressing challenge.

Currently, most of the existing three-dimensional stacked optoelectronic packaging structures directly bond the photonic integrated chip and electrical integrated chip on the substrate, and electrically connect them to the substrate through wire-bonds or Flip-Chip techniques. However, the silicon photonics process nodes are relatively outdated compared to the electronic chip processes. For instance, the most advanced silicon photonics process nodes are 45 nm and 32 nm, which are significantly behind the sub-10nm process nodes existing in the electronic chips. As a result, the performance of existing optoelectronic integrated packaging structures often falls short of meeting the high-density integration requirements.

In the existing technology, there is also the use of system-on-chip (SOC) packaging to change the chip design in order to improve the density of package integration, but this approach has to improve in the front-channel process on the optical chip, in order to bring the optical chip reach 10 nm or less so to match the electronic chip's at the process node, however this way of packaging undoubtedly increases the process cost.

### SUMMARY

The present disclosure provides a method for preparing a three-dimensional stacked optoelectronic packaging structure, to integrate the photonic chip with the electronic chips in a high-density integrated package.

The present disclosure provides a method of preparing a three-dimensional stacked optoelectronic packaging structure, comprising the following steps: providing a substrate;
forming a separation layer on the substrate;
providing electronic chips and bonding the electronic chips onto the separation layer, wherein electronic chip pads of the electronic chips are in contact with the separation layer;
forming an encapsulation layer over the separation layer, wherein the encapsulation layer covers the electronic chips;
removing the separation layer and the substrate to expose the encapsulation layer and the electronic chips;
forming a redistribution layer over the encapsulation layer, wherein the redistribution layer comprises a first surface and an opposing second surface, and the first surface of the redistribution layer is in contact with the encapsulation layer and the electronic chips, the redistribution layer is electrically connected to the electronic chip pads;
forming the first connection bumps and the second connection bumps on the second surface of the redistribution layer, where both the first connection bumps and the second connection bumps are electrically connected to the redistribution layer, herein a height of the second connection bumps is greater than a height of the first connection bumps;
providing a board comprising a first surface and an opposing second surface, where the first surface of the board has board pads;
providing a photonic chip and bonding it to the first surface of the board with the photonic chip being offset relative to the board pads, wherein both the photonic chip pads and a photosensitive area of the photonic chip face away from a bonding surface;
bonding the first connection bumps to the photonic chip pads, and bonding the second connection bumps to the board pads, wherein the first connection bumps are electrically connected to the photonic chip pads, and the second connection bumps are electrically connected to the board pads, exposing the photosensitive area of the photonic chip;
bonding optical fibers onto the photonic chip, wherein the optical fibers connect with the photosensitive area of the photonic chip; and
providing a heat dissipation cover plate, bonding the heat dissipation cover plate to the first surface of the board, where the heat dissipation cover plate directly or indirectly contacts with the electronic chips, the heat dissipation cover plate covers the electronic chips and the photonic chip, and the heat dissipation cover plate has an opening exposing the optical fibers.

Optionally, the first connecting bumps are solder bumps, or the first connecting bumps comprises metal pillars and solder bumps located above the metal pillars, or the first connecting bumps comprise metal bumps and solder layers on outer surfaces of the metal bumps; wherein the second connecting bumps are solder bumps, or the second connecting bumps comprise metal pillars and solder bumps located above the metal pillars, or the second connecting bumps comprise metal bumps and solder layers on outer surfaces of the metal bumps.

Optionally, a height of the first connecting bumps is in a range of 30 to 150 μm, and a height of the second connecting bumps is in a range of 200 to 600 μm.

Optionally, the photonic chip, the electronic chips and the substrate follow different process nodes that are bridged and interconnected by the rewiring layer, the first connection bumps and the second connection bumps.

Optionally, the three-dimensional stacked optoelectronic packaging structure formed has a minimum line width of 1 to 2 μm and a minimum line spacing of 1 to 2 μm.

Optionally, the substrate comprises one of a glass substrate, a metal substrate, a semiconductor substrate, a polymer substrate, and a ceramic substrate; and the separation layer comprises a UV-curable separation layer or a thermally-curable separation layer.

Optionally, the method of forming the encapsulation layer comprises one of compression molding, transfer molding, liquid encapsulation, vacuum lamination, and spin coating, and further comprises thinning the encapsulation layer after its formation.

Optionally, the method further comprises: forming a bottom filling layer between the redistribution layer and the board to cover the first connection bumps and the second connection bumps.

Optionally, the encapsulation layer further comprises a layer of thermal adhesive material on a surface away from the redistribution layer, and the thermal adhesive material contacts with the heat dissipation cover plate.

Optionally, a layer of thermal adhesive material or the encapsulation layer is positioned between the heat dissipation cover plate and the electronic chips.

Optionally, the method further comprises: forming a bottom filling layer between the redistribution layer and the board to cover the first connection bumps and the second connection bumps.

Optionally, the method further comprises: forming metal bumps on a second surface of the substrate.

The present disclosure also provides a three-dimensional stacked optoelectronic packaging structure, the three-dimensional stacked optoelectronic packaging structure comprising:
a redistribution layer, wherein the redistribution layer comprises a first surface and a second surface opposite to the first surface;
electronic chips, wherein the electronic chips are bonded to the first surface of the redistribution layer, and the electronic chip pads of the electronic chips are electrically connected to the redistribution layer;
an encapsulation layer, wherein the encapsulation layer is located over the first surface of the redistribution layer and covers the electronic chips;
first connection bumps and second connection bumps, wherein the first connection bumps and the second connection bumps are both located over the second surface of the redistribution layer, the first connection bumps and the second connection bumps are both electrically connected to the redistribution layer. The height of the second connection bumps is greater the height of the first connection bumps;
a board, wherein the board comprises a first surface and an opposing second surface, the first surface of the board is disposed with board pads;
a photonic chip, wherein the photonic chip is bonded to the first surface of the board and is arranged in an offset manner relative to the board pads, the photonic chip pads and a photosensitive area of the photonic chip face away from a bonding surface, the first connection bumps are bonded to the photonic chip pads, and the second connection bumps are bonded to the board pads, the first connection bumps are electrically connected to the photonic chip pads, and the second connection bumps are electrically connected to the board pads, exposing the photosensitive area of the photonic chip;
an optical fiber, wherein the optical fiber connects onto the photonic chip and connects with the photosensitive area of the photonic chip;
a heat dissipation cover plate, wherein the heat dissipation cover plate is bonded to the first surface of the board, covering both the electronic chips and the photonic chip, and the heat dissipation cover plate has an opening exposing the optical fiber;

Optionally, the three-dimensional stacked optoelectronic packaging structure has a minimum line width of 1 to 2 μm and a minimum line spacing of 1 to 2 μm.

Optionally, a height difference between the first connecting bumps and the second connecting bumps is set according to thickness of the photonic chip, the electronic chips are positioned flat on the board and the photonic chip.

Optionally, the heat dissipation cover plate is in direct or indirect contact with the photonic chip.

Optionally, a layer of thermal adhesive material or the encapsulation layer is positioned between the heat dissipation cover plate and the electronic chips.

As described above, the three-dimensional stacked optoelectronic packaging structure and preparation method of the present disclosure utilize a three-dimensional stacked fan-out packaging approach to effectively shorten the transmission path between photonic chips and electronic chips. This increases efficiency, reduces packaging size, and enables high-density integration of chips with different process nodes through subsequent processes. It optimizes high-density integration layout and ensures that the electronic integrated circuit packaging is in even contact with the heat dissipation cover plate, addressing the thermal management needs of the optoelectronic packaging structure.

### BRIEF DESCRIPTION OF THE DRAWINGS

FIG. 1 shows a flowchart illustrating a three-dimensional stacked optoelectronic packaging structure of the present disclosure.

FIG. 2 shows a schematic diagram of a packaging structure after forming the separation layer over the substrate according to the present disclosure.

FIG. 3 shows a schematic diagram of a packaging structure after bonding the electronic chips over the substrate according to the present disclosure.

FIG. 4 shows a schematic diagram of a packaging structure after forming the encapsulation layer over the electronic chip according to the present disclosure.

FIG. 5 shows a schematic diagram of a packaging structure after the removal of the separation layer and substrate according to the present disclosure.

FIG. 6 shows a schematic diagram of a packaging structure after forming the first connection bumps and the second connection bumps according to the present disclosure.

FIG. 7 shows a schematic diagram of a packaging structure after bonding the photonic chip onto a board according to the present disclosure.

FIG. 8 shows a schematic diagram of a packaging structure after bonding the first connection bumps to the photonic chip pads and bonding the second connection bumps to the substrate pads according to the present disclosure.

FIG. 9 shows a schematic diagram of a packaging structure after forming the bottom filling layer among the connection bumps according to the present disclosure.

FIG. 10 shows a schematic diagram of a packaging structure after bonding the heat dissipation cover plate over the top of the packaging structure according to the present disclosure.

FIG. 11 shows a partial perspective schematic diagram of an embodiment of the three-dimensional stacked optoelectronic packaging structure according to the present disclosure.

### REFERENCE NUMERALS

100 Substrate
200 Separation layer
300 Electronic chips
301 Electronic chip pads
400 Encapsulation layer
500 Redistribution layer
610 First connecting bumps
620 Second connecting bumps
700 Board
701 Board pads
800 Photonic chip
801 Photonic chip pads
802 Photosensitive area of the photonic chip
900 Bottom filling layer
110 Optical fiber
120 Heat dissipation cover plate
130 Metal bumps
140 Thermal adhesive material

### DETAILED DESCRIPTION

The embodiments of the present disclosure will be described below. Those skilled can easily understand advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

When describing the embodiments of the present disclosure, for better explanation, cross-sectional structural diagrams may be partially enlarged without following the general scale. Moreover, the diagrams are only examples and should not limit the scope of the present disclosure. In addition, the actual production should comprise the length, width and depth of the three-dimensional space dimensions.

For the convenience of description, spatial relation terms such as “below”, “under”, “beneath”, “on”, “above”, “up”, etc. may be used herein to describe the relationships between an element or feature and other elements or features. It will be understood that these spatial relationship terms are intended to encompass directions/orientations of the device in use or operation other than those depicted in the drawings. In addition, when a first layer is referred to as being “between” a second layer and a third layer, the first layer may be the only layer between the second and third layers, or there may more layers between the two layers. Wherein, when an element is “fixed onto” or “disposed on” another element, it may be directly or indirectly on the other element. When an element is “attached to” or “connected to” another element, it may be directly or indirectly attached/connected to the other element.

Expressions such as “between . . . ” may be used herein to indicate that two endpoints of the range are included, and expressions such as “several” may be used to indicate two or more, unless explicitly and specifically qualified otherwise. In addition, the terms like “first” and “second” are used for descriptive purpose only, and are not to be construed as indicating or implying relative importance or implicitly specifying numbers of technical features indicated. Thus, features qualified with terms like “first” and “second” may explicitly or implicitly comprise one or more such features.

It should be noted that the drawings provided in this disclosure only illustrate the basic concept of the present disclosure in a schematic way, so the drawings only show the components closely related to the present disclosure. The drawings are not necessarily drawn according to the number, shape and size of the components in actual implementation; during the actual implementation, the type, quantity and proportion of each component can be changed as needed, and the components' layout may also be more complicated.

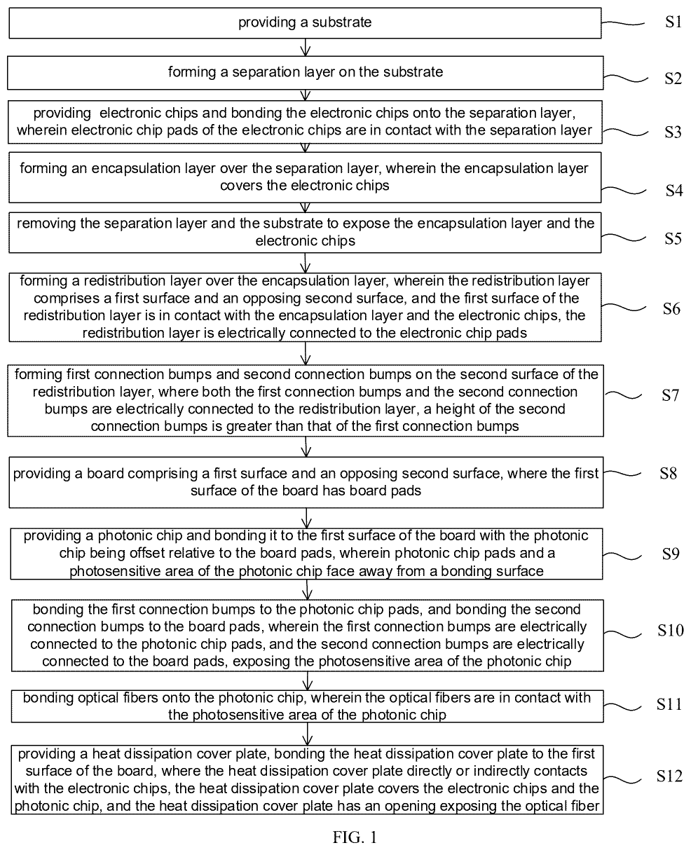

As shown in FIG. 1, the present disclosure provides a method for preparing a three-dimensional stacked optoelectronic packaging structure with a three-dimensional stacked fan-out packaging approach. This method effectively shortens the optical transmission path between the photonic chips and electronic chips, enhancing performance and reducing package size. It allows for high-density integration of optical and electronic chips at different process nodes through subsequent processes. Additionally, it optimizes the high-density integration layout and ensures that the electronic circuit packaging is in smooth contact with the heat dissipation cover plate, addressing thermal management needs for the optoelectronic packaging structure.

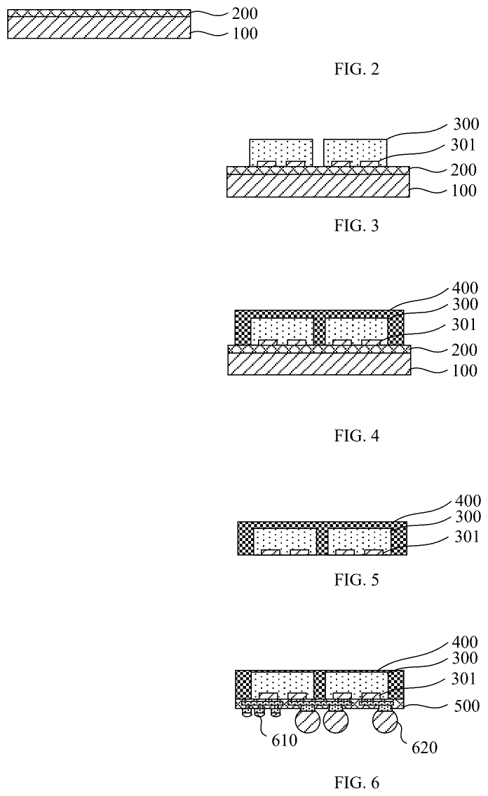

The following provides a detailed introduction to the preparation of the three-dimensional stacked optoelectronic packaging structure with reference to FIG. 2-FIG. 11, comprising:

First, referring to FIG. 2, execute step S1 to provide a substrate 100.

As an example, the substrate 100 comprises one of a glass substrate, a metal substrate, a semiconductor substrate, a polymer substrate, and a ceramic substrate. The substrate 100 can comprises wafer-level substrates with dimensions of 8 inches or 12 inches to enhance process efficiency. However, the size of the substrate 100 is not limited to these dimensions; its material and size can be chosen according to specific requirements.

Further, referring to FIG. 2, execute step S2 by forming a separation layer 200 on the substrate 100.

As an example, the separation layer 200 may comprises a UV-curable separation layer or a thermally-curable separation layer.

Specifically, the separation layer 200 may be a polymer film that is formed by applying a spin-coating process followed by UV curing or thermal curing. This method ensures that the polymer film is solidified and adhered to the substrate 100 effectively. Using the separation layer 200 facilitates the subsequent removal of the substrate 100 while minimizing damage to the components. However, the type of separation layer 200 is not limited to polymer films; it can also be other materials such as adhesive tapes or similar alternatives, depending on the specific needs of the process.

Further, referring to FIG. 3, execute step S3 by providing electronic chips 300. One side of the electronic chips 300 is provided electronic chip pads 301. The electronic chips 300 is bonded to the separation layer 200 such that the electronic chip pads 301 of the electronic chips 300 are in contact with the separation layer 200.

Specifically, the electronic chips 300 are bonded to the separation layer 200 by means of Flip-Chip, wherein the process node of the electronic chips 300 may be 10 nm or less.

Preferably, the electronic chips 300 are provided in multiple units. This allows for subsequent processes to integrate and consolidate multiple electronic chips 300, thereby enhancing the overall performance of the chips. This approach facilitates increased functionality, reliability, and processing power by leveraging the combined capabilities of the multiple electronic chips 300. The multiple electronic chips 300 can either be identical or different from each other.

Preferably, the thickness of each of the electronic chips 300 should be the same or close to each other.

Further, referring to FIG. 4, execute step S4 by forming the encapsulation layer 400 on the separation layer 200, wherein the encapsulation layer 400 will cover the electronic chips 300.

As an example, the method of forming the encapsulation layer 400 comprises one of compression molding, transfer molding, liquid encapsulation, vacuum lamination, and spin coating, and further comprises thinning the encapsulation layer 400 after its formation. This step helps to minimize the overall dimensions of the package.

Specifically, the material for the encapsulation layer 400 may comprise substances such as epoxy resin or polyimide. After forming the encapsulation layer 400, thinning of the encapsulation layer 400 can be achieved using methods such as Chemical Mechanical Planarization (CMP). This process further reduces the dimensions of the encapsulated structure, allowing the encapsulation layer 400 on the side of the electronic chips 300 opposite to the separation layer 200 to be thinned or removed. This thinning or removal helps to enhance the heat dissipation from the electronic chips 300, thereby reducing the impact of temperature on the electronic chips 300. Preferably, the top of the electronic chips 300 are exposed from the encapsulation layer 400 after thinning.

Further, referring to FIG. 5, execute step S5 to remove the separation layer 200 and the substrate 100, exposing the encapsulation layer 400 and the electronic chips 300 from their bottoms.

Specifically, since the separation layer 200 is either an UV-curable separation layer or a thermally-curable separation layer, it can be effectively removed by applying UV light or heat. This allows for convenient removal of both the separation layer 200 and the substrate 100. In the previous mentioned step S3, the electronic chips 300 and its electronic chip pads 301 are in contact with the separation layer 200, and thus in this step S5, the separation layer 200 and the substrate 100 are removed, and exposing the side of the electronic chips 300 having the electronic chip pads 301.

Further, referring to FIG. 6, execute step S6 to form a redistribution layer 500 onto the encapsulation layer 400 and the electronic chips 300 from the bottom side. The redistribution layer 500 comprises a first surface and an opposing second surface. The first surface of the redistribution layer 500 is in contact with both the encapsulation layer 400 and the electronic chips 300 at their bottoms, and the redistribution layer 500 is electrically connected to the electronic chip pads 301.

Further, referring to FIG. 6, execute step S7 to form first connection bumps 610 and second connection bumps 620 on a second surface of the redistribution layer 500, wherein the first connection bumps 610 and the second connection bumps 620 are both electrically connected to the redistribution layer 500, and the height of the first connection bumps 610 is different from the height of the second connection bumps 620. In one embodiment, the height of the second connection bumps 620 is greater than the height of the first connection bumps 610.

As an example, the first connecting bumps 610 are solder bumps, or the first connecting bumps 610 comprises both metal pillars and solder bumps (not shown in the figures) located above the metal pillars, or the first connecting bumps 610 comprise metal bumps and solder layers on outer surfaces of the metal bumps (not shown in figures); wherein the second connecting bumps 620 are solder bumps, or the second connecting bumps 620 comprise both metal pillars and solder bumps (not shown in figures) located above the metal pillars, or the second connecting bumps 620 comprise metal bumps and solder layers on outer surfaces of the metal bumps (not shown in figures).

Further, the substrate 100 is connected to the electronic chip pads 301 by a bonding adhesive layer 302 (not shown in figures).

Specifically, the materials for the metal pillars and metal bumps can comprise copper, nickel, or a combination of these. The material for the solder bumps can comprise copper, nickel, gold, tin, silver, or a combination of these. Regarding the materials and preparation of the first connection bumps 610 and the second connection bumps 620, as long as the height difference between the second connection bumps 620 and the first connection bumps 610 is maintained to facilitate subsequent electrical connections with a board 700 and a photonic chip 800. The preferred height difference should match the height at which the photonic chip 800 is bonded to the board 700, ensuring a flat and uniform bonding structure.

For example, the height of the first connection bumps 610 can range from 30 to 150 μm, with specific heights such as 30 μm, 50 μm, 100 μm, or 150 μm. The height of the second connection bump 620 can range from 200 to 600 μm, with specific heights such as 200 μm, 300 μm, 400 μm, or 600 μm.

After executing step S6, an electrical integrated circuit package is formed. The electrical integrated circuit package comprises the following components: the electronic chips 300, the encapsulation layer 400 that covers the electronic chips 300, the redistribution layer 500 formed on both the encapsulation layer 400 and the electronic chips 300, and the first connection bumps 610 and the second connection bumps 620 formed on the surface of the redistribution layer 500 away from the chip 300.

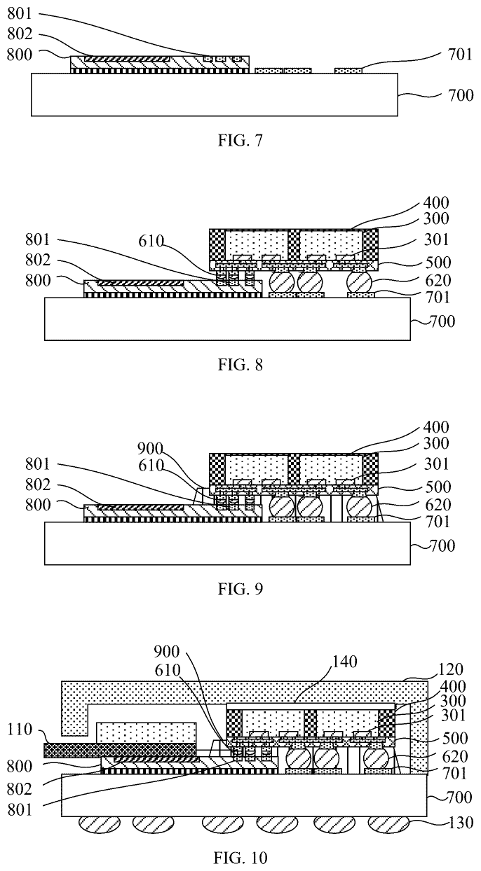

Further, referring to FIG. 7, execute step S8 to provide a board 700, the board 700 comprising a first surface and an opposite second surface. The board 700 has board pads 701 on the first surface.

Specifically, the board 700 may be a PCB substrate.

Further, referring to FIG. 7, execute step S9 to provide a photonic chip 800, one surface of the photonic chip 800 has photonic chip pads 801 and a photosensitive area 802 of the photonic chip 800, and the photonic chip 800 is bonded to a surface of the board 700 on the surface opposite to its photonic chip pads 801 and photosensitive area 802 of the photonic chip 800, and is offset relative to the board pads 701.

Specifically, the type of photonic chip 800 can be selected based on requirements, such as a photonic chip at a larger electronic process node, for example, photonic chips at 45 nm and 32 nm processes.

The height difference between the first connecting bumps 610 and the second connecting bumps 620 is set according to the thickness of the photonic chip 800.

As an example, the photonic chip 800, the electronic chips 300, and the board 700 undergo different process nodes. Bridging interconnection are realized through the redistribution layer 500, the first connecting bumps 610, and the second connecting bumps 620. The selection of process nodes for connection to the photonic chip 800, the electronic chips 300 and the board 700 can be carried out separately as needed, so that high-density integrated packaging can be conveniently realized.

Next, referring to FIG. 8, execute step S10 by bonding the first connection bumps formed in the previous step S7 to the photonic chip pads 801, bonding the second connecting bumps 620 to the board pads 701. The first connecting bumps 610 are electrically connected to the photonic chip pads 801, and the second connecting bumps 620 are electrically connected to the board pads 701, exposing the photosensitive area 820 of the photonic chip 800. The electrical connection between the electronic chips 300 and the photonic chip 800 is achieved through the redistribution layer 500 and the first connecting bumps 610. The electrical integrated circuit package is electrically connected to the photonic chip 800 in a face-to-face offset configuration. Specifically, the electronic chip pads 301 of the electronic chips 300 are arranged facing the photonic chip pads 801 of the photonic chip 800. This arrangement facilitates high-density integration of the electrical chips 300, photonic chip 800, and other components, while effectively shortening the transmission path between the electronic chips 300 and the photonic chip 800, the varying heights of the first connecting bumps 610 and the second connecting bumps 620 enable the electronic chips 300 to be positioned flat on the board 700 and the photonic chip 800, which helps ensure better thermal contact between the heat dissipation cover plate 120 and the electronic chips 300.

As an example, the process also comprises forming a bottom filling layer 900 between the redistribution layer 500 and the board 700 to encapsulate the first connecting bumps 610 and the second connecting bumps 620. The bottom filling layer 900 protects both the redistribution layer 500 and the board 700, while also safeguarding the electrical connection points between the first connecting bumps 610 and the redistribution layer 500, as well as between the photonic chip pads 801, and the electrical connection points between the second connecting bumps 620, the redistribution layer 500, and the board pads 701, as shown in FIG. 9. The material of the bottom filling layer 900 can be chosen according to practical applications, provided it is an electrical insulating material.

Further, referring to FIG. 10, execute step S11 by providing an optical fiber 110 and bonding it to the photonic chip 800, with the optical fiber 110 in contact with the photosensitive area 802 of the photonic chip 800.

Optionally, the photonic chip 800 may comprise multiple units, each of which is offset relative to the board pads 701. The optical fiber 110 may also comprise multiple units, with each optical fiber 110 in contact with the photosensitive area 802 of the corresponding photonic chip 800.

Further, execute step S12 by providing a heat dissipation cover plate 120, bonding the heat dissipation cover plate 120 to the first surface of the board 700, the heat dissipation cover plate 120 encapsulating the electronic chips 300 and the photonic chip 800 and being in direct or indirect contact with the electronic chips 300 in order to conduct heat generated by the operation of the electronic chips 300 and to reduce the effect of temperature on the electronic chips 300, and the heat dissipation cover plate 120 having an opening exposing the optical fiber 110.

Specifically, the heat dissipation cover plate 120 may be an aluminum heat sink cover or a heat sink cover made of other materials, such as iron, copper, etc. To facilitate subsequent electrical connections, the second surface of the board 700 may also have metal bumps 130 formed, which are electrically connected to the substrate pads 701 on its first surface, allowing the photonic chip 800 and the electronic chip 300 to be connected through the board 700 to the metal bumps 130. The metal bumps 130 can be materials such as solder balls prepared using a reflow soldering process, but are not limited to these. The specific material and preparation method for the metal bumps 130 are not restricted here.

Specifically, the heat dissipation cover plate 120 is in direct contact with the encapsulation layer 400 on the thinned surface in the preceding step S4. In other words, when the thickness is reduced to the point where the electronic chip 300 is exposed through the encapsulation layer 400, the heat dissipation cover plate 120 makes direct thermal contact with the electrical chips 300; when the thickness is reduced to the point where the electrical chips 300 are not exposed through the encapsulation layer 400, the heat dissipation cover 120 makes indirect thermal contact through a thin layer of the encapsulation layer 400.

Specifically, the heat dissipation cover plate 120 can also indirectly contact with the encapsulation layer 400 from the thinning step S4 through a layer of the thermal adhesive material 140. In other words, when the thickness is reduced to the point where the electronic chips 300 are exposed through the encapsulation layer 400, as shown in FIG. 10, the heat dissipation cover plate 120 indirectly contacts with the electronic chip 300 through the thermal adhesive material 140, when the thickness is reduced to the point where the electronic chip 300s are not exposed through the encapsulation layer 400, the heat dissipation cover plate 120 indirectly contacts with the electronic chips 300 through a layer of thermal adhesive material 140 and a thin layer of the encapsulation layer 400.

As an example, a minimum line width in the three-dimensional stacked optoelectronic packaging structure can be 1 to 2 μm, and a minimum line spacing can be 1 to 2 μm.

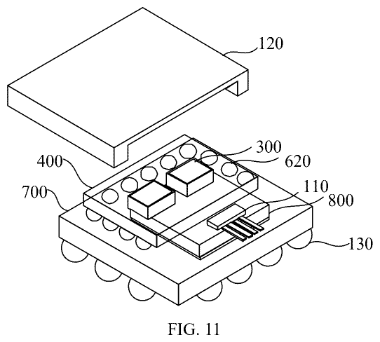

Specifically, based on the redistribution layer 500 and the interleaved stacking of the redistribution layer 500 with the photonic chip 800, the minimum line width in the three-dimensional stacked optoelectronic packaging structure can reach 1 to 2 μm, such as 1μm, 1.5 μm, or 2 μm, and the minimum line spacing can also reach 1 to 2 μm, such as 1 μm, 1.5 μm, or 2 μm. This allows for the co-packaging of the photonic chip 800 and the electronic chips 300, effectively shortening the transmission path between them, increasing efficiency, reducing packaging size, and minimizing the line width and spacing in the packaging structure. Consequently, high-density integration and packaging of chips with different process nodes from different eras can be achieved through subsequent packaging processes. To further illustrate the morphology of the three-dimensional stacked optoelectronic packaging structure, FIG. 11 additionally shows a perspective view of the structure. Combining FIG. 10 and FIG. 11, it is evident that the electrical integrated circuit package, with its first connection bumps 610 and second connection bumps 620 of different heights, can be positioned flat on the photonic chip 800 and the board 700, with the photonic chip 800 exposed for light reception. The heat dissipation cover plate is mounted on the encapsulation layer 400 and makes direct or indirect thermal contact with the electronic chips 300, while having an opening exposing the optical fiber 110.

Refer to FIG. 2 to FIG. 11. The present disclosure also provides a three-dimensional stacked optoelectronic packaging structure, which comprises the redistribution layer 500, the electronic chips 300, the encapsulation layer 400, the first connection bumps 610, the second connection bumps 620, the board 700, the photonic chip 800, the optical fiber 110, and the heat dissipation cover plate 120.

The redistribution layer 500 comprises a first surface and an opposing second surface, one surface of the electrical chips 300 has electronic chip pads 301, and the electrical chips 300 are bonded to the first surface of the redistribution layer 500, with the electrical chip pads 301 electrically connected to the redistribution layer 500. The encapsulation layer 400 is positioned on the first surface of the redistribution layer 500 and covers the electronic chips 300. Both the first connection bumps 610 and the second connection bumps 620 are located over the second surface of the redistribution layer 500, with each bump electrically connected to the redistribution layer 500. The height of the second connection bumps 620 is greater than the height of the first connection bumps 610. The redistribution layer 500, the electronic chips 300, the encapsulation layer 400, the first connection bumps 610, and the second connection bumps 620 together constitute the electrical integrated circuit package.

Optionally, the first connection bumps 610 may be solder bumps, or the first connection bumps 610 may comprise metal pillars with solder bumps located above the metal pillars (not shown in figures), or the first connection bumps 610 may comprise metal bumps with solder layers on outer surfaces of the metal bumps (not shown in figures).

Optionally, the first connection bumps 620 may be solder bumps, or the first connection bumps 620 may comprise metal pillars with solder bumps located above the metal pillars (not shown in figures), or the first connection bumps 620 may comprise metal bumps with solder layers on outer surfaces of the metal bumps (not shown in figures).

The board 700 comprises a first surface and an opposing second surface, the first surface of the board 700 having a board pad 701. One surface of the photonic chip 800 has photonic chip pads 801 and the photosensitive area 802 of the photonic chip 800. The photonic chip 800 is bonded to the first surface of the board 700 on the surface opposite to its photonic chip pads 801 and photosensitive area 802, with the photonic chip pad 801 and the photosensitive area 802 of the photonic chip 800 offset relative to the board pads 701. The electrical integrated circuit package and the photonic chip 800 are arranged in an interleaved manner, facing each other, with the first connection bumps 610 bonded to the photonic chip pads 801, and the second connection bumps 620 bonded to the board pad 701. The first connection bumps 610 are electrically connected to the photonic chip pads 801, and the second connection bumps 620 are electrically connected to the board pads 701, exposing the photosensitive area 802 of the photonic chip 800. The optical fiber 110 is bonded to the photonic chip 800 and is in contact with the photosensitive area 802 of the photonic chip 800. The heat dissipation cover plate 120 is bonded to the first surface of the board 700, covering the electrical chip 300 and the photonic chip 800, and is in direct or indirect contact with the electronic chips 300. The heat dissipation cover plate 120 has an opening exposing the optical fiber 110.

The electrical chips 300 and the photonic chip 800 are electrically positioned on opposite sides of the redistribution layer 500, which effectively shortens the transmission path between the photonic chip and the electronic chips, enhances performance, and reduces the packaging size.

The height difference between the first connecting bumps 610 and the second connecting bumps 620 is set based on the thickness of the photonic chip 800, so that the electrical integrated circuit package is positioned flat on top of the board 700 and the photonic chip 800, in order to facilitate a better contact heat conduction between the heat dissipation cover plate 120 and the electronic chips 300.

Preferably, the electronic chips 300 are exposed from the encapsulation layer 400, and the heat dissipation cover plate 120 is arranged to be in direct contact with the electronic chips 300.

Preferably, the electronic chips 300 are exposed to the encapsulation layer 400, and the heat dissipation cover plate 120 is set in indirect contact with the electronic chips 300 spaced apart by a layer of thermal adhesive material 140.

Optionally, the electronic chips 300 are not exposed from the encapsulation layer 400, the heat dissipation cover plate 120 is arranged to indirectly contact with the electronic chip 300 through a thin layer of the encapsulation layer 400.

Optionally, the electronic chips 300 are not exposed from the encapsulation layer 400, the heat dissipation cover plate 120 is arranged to indirectly contact with the electronic chips 300 through a layer of thermal adhesive material 140 and a thin layer of the encapsulation layer 400. Specifically, the three-dimensional stacked optoelectronic packaging structure can be prepared using the aforementioned manufacturing method, but it is not limited to this. In one embodiment, the three-dimensional stacked optoelectronic packaging structure is prepared using the described method, and therefore, the details regarding the preparation and structure of the three-dimensional stacked optoelectronic packaging structure will not be repeated here.

As an example, the three-dimensional stacked optoelectronic packaging structure has a minimum line width of 1 to 2 μm and a minimum line spacing of 1 to 2 μm.

Specifically, based on the redistribution layer 500 and its interleaved stacking with the photonic chip 800, the minimum line width in the three-dimensional stacked optoelectronic packaging structure can be reduced to 1-2 μm, such as 1 μm, 1.5 μm, or 2 μm. The minimum line spacing in the structure can also reach 1-2 μm, such as 1 μm, 1.5 μm, or 2 μm. This allows for the co-packaging of the photonic chip 800 and the electronic chips 300, effectively shortening the transmission path between them, increasing efficiency, and reducing the package size. It also enables a reduction in the line width and spacing of the packaging structure. Consequently, high-density integration of chips from different eras with varying process nodes can be achieved through the back-end packaging process alone. To further illustrate the morphology of the three-dimensional stacked optoelectronic packaging structure, FIG. 11 also shows a perspective view of the structure. Combining FIG. 10 and FIG. 11, it is evident that the integrated circuit package with its first connection bumps 610 and second connection bumps 620, having different heights, can be mounted flatly on the photonic chip 800 and board 700, exposing the side of the photonic chip 800 for optical reception. The heat dissipation cover plate is mounted on the packaging layer 400 and is in direct or indirect thermal contact with the electronic chips 300, and has an opening exposing the optical fiber 110.

In summary, the three-dimensional stacked optoelectronic packaging structure and its preparation method leverage a three-dimensional stack with mixed fan-out packaging. The interleaved arrangement of the electrical integrated circuit package and the photonic chip, combined with first connection bumps and second connection bumps of different heights, effectively shortens the transmission paths between the photonic chip and the electronic chips, enhances efficiency, and reduces package size. This allows for high-density integration and packaging of the photonic and the electronic chips with different process nodes through back-end processes, optimizing the layout for high-density integration while ensuring that the electrical integrated circuit package and the heat dissipation cover plate are positioned flat against each other, thus meeting the thermal management needs of the optoelectronic packaging structure.

The above-mentioned embodiments are merely illustrative of the principle and effects of the present disclosure instead of restricting the scope of the present disclosure. Any person skilled in the art may modify or change the above embodiments without violating the principle of the present disclosure. Therefore, all equivalent modifications or changes made by those who have common knowledge in the art without departing from the spirit and technical concept disclosed by the present disclosure shall be still covered by the claims of the present disclosure.

What is claimed is:

1. A method for preparing a three-dimensional stacked optoelectronic packaging structure, comprising:
providing a substrate;
forming a separation layer on the substrate;
providing electronic chips and bonding the electronic chips onto the separation layer, wherein electronic chip pads of the electronic chips are in contact with the separation layer;
forming an encapsulation layer over the separation layer, wherein the encapsulation layer covers the electronic chips;
removing the separation layer and the substrate to expose the encapsulation layer and the electronic chips;
forming a redistribution layer over the encapsulation layer, wherein the redistribution layer comprises a first surface and an opposing second surface, wherein the first surface of the redistribution layer is in contact with the encapsulation layer, and wherein the redistribution layer is electrically connected to the electronic chip pads;
forming first connection bumps and second connection bumps on the second surface of the redistribution layer, wherein both the first connection bumps and the second connection bumps are electrically connected to the redistribution layer, wherein a height of the second connection bumps is greater than a height of the first connection bumps;
providing a board comprising a first surface and an opposing second surface, wherein the first surface of the board is provided with board pads;
providing a photonic chip having photonic chip pads and bonding the photonic chip to the first surface of the board with the photonic chip being offset relative to the board pads, wherein the photonic chip pads and a photosensitive area of the photonic chip face away from the first surface of the board;
bonding the first connection bumps to the photonic chip pads, and bonding the second connection bumps to the board pads, wherein the first connection bumps are electrically connected to the photonic chip pads, and the second connection bumps are electrically connected to the board pads, wherein the photosensitive area of the photonic chip is exposed;
bonding optical fibers onto the photonic chip, wherein the optical fibers are in optical contact with the photosensitive area of the photonic chip; and
providing a heat dissipation cover plate, bonding the heat dissipation cover plate to the first surface of the board, wherein the heat dissipation cover plate covers the electronic chips and the photonic chip, wherein the heat dissipation cover plate directly or indirectly contacts with the electronic chips, and wherein the heat dissipation cover plate has an opening as an exit to the optical fibers.

2. The method for preparing a three-dimensional stacked optoelectronic packaging structure according to claim 1, wherein the first connecting bumps comprise one of solder bumps, solder bumps disposed on metal pillars, and solder layers coated on metal bumps; and wherein the second connecting bumps comprise one of solder bumps, solder bumps disposed on the metal pillars, and solder layers coated on metal bumps.

3. The method for preparing a three-dimensional stacked optoelectronic packaging structure according to claim 1, wherein a height of the first connecting bumps is in a range of 30 to 150 μm, and a height of the second connecting bumps is in a range of 200 to 600 μm.

4. The method for preparing a three-dimensional stacked optoelectronic packaging structure according to claim 1, wherein the photonic chip, the electronic chips, and the board are fabricated at different semiconductor process nodes, and wherein bridging interconnection is realized through the redistribution layer, the first connecting bumps, and the second connecting bumps.

5. The method for preparing a three-dimensional stacked optoelectronic packaging structure according to claim 1, wherein the three-dimensional stacked optoelectronic packaging structure has a minimum line width of 1 to 2 μm and a minimum line spacing of 1 to 2 μm.

6. The method for preparing a three-dimensional stacked optoelectronic packaging structure according to claim 1, wherein the substrate comprises one of a glass substrate, a metal substrate, a semiconductor substrate, a polymer substrate, or a ceramic substrate; the separation layer comprises a UV-curable separation layer or a thermally-curable separation layer.

7. The method for preparing a three-dimensional stacked optoelectronic packaging structure according to claim 1, wherein the method of forming the encapsulation layer comprises one of compression molding, transfer molding, liquid encapsulation, vacuum lamination, and spin coating, and further comprises thinning the encapsulation layer after its formation.

8. The method for preparing a three-dimensional stacked optoelectronic packaging structure according to claim 1, wherein the encapsulation layer further comprises a layer of thermal adhesive material on a surface away from the redistribution layer, and the thermal adhesive material contacts with the heat dissipation cover plate.

9. The method for preparing a three-dimensional stacked optoelectronic packaging structure according to claim 8, wherein the layer of thermal adhesive material or the encapsulation layer is positioned between the heat dissipation cover plate and the electronic chips.

10. The method for preparing a three-dimensional stacked optoelectronic packaging structure according to claim 1, further comprising: forming a bottom filling layer between the redistribution layer and the board to cover the first connection bumps and the second connection bumps.

11. The method for preparing a three-dimensional stacked optoelectronic packaging structure according to claim 1, further comprising: forming metal bumps on the second surface of the board.

12. A three-dimensional stacked optoelectronic packaging structure, wherein the three-dimensional stacked optoelectronic packaging structure comprises:
a redistribution layer, wherein the redistribution layer comprises a first surface and a second surface opposite to the first surface;
electronic chips, wherein the electronic chips are bonded to the first surface of the redistribution layer, and the electronic chip pads of the electronic chips are electrically connected to the redistribution layer;
an encapsulation layer, wherein the encapsulation layer is located over the first surface of the redistribution layer and covers the electronic chips;
first connection bumps and second connection bumps, wherein the first connection bumps and the second connection bumps are both located over the second surface of the redistribution layer, and the first connection bumps and the second connection bumps are both electrically connected to the redistribution layer, and wherein a height of the second connection bumps is greater than a height of the first connection bumps;
a board, wherein the board comprises a first surface and an opposing second surface, wherein the first surface of the board has board pads;
a photonic chip, wherein the photonic chip is bonded to the first surface of the board and is arranged in an offset manner relative to the board pads, wherein the photonic chip pads and a photosensitive area of the photonic chip face away from the first surface of the board, wherein the first connection bumps are bonded to the photonic chip pads, and the second connection bumps are bonded to the board pads, wherein the first connection bumps are electrically connected to the photonic chip pads, and the second connection bumps are electrically connected to the board pads, and wherein the photosensitive area of the photonic chip is exposed;
an optical fiber, wherein the optical fiber is bonded onto the photonic chip and in an optical contact with the photosensitive area of the photonic chip; and
a heat dissipation cover plate, wherein the heat dissipation cover plate is bonded to the first surface of the board, covering both the electronic chips and the photonic chip, and the heat dissipation cover plate has an opening exposing the optical fiber.

13. The three-dimensional stacked optoelectronic packaging structure according to claim 12, wherein the three-dimensional stacked optoelectronic packaging structure has a minimum line width of 1 to 2 μm and a minimum line spacing of 1 to 2 μm.

14. The three-dimensional stacked optoelectronic packaging structure according to claim 12, wherein a height difference between the first connecting bumps and the second connecting bumps is set according to thickness of the photonic chip, and wherein the electronic chips are disposed parallel to the board and the photonic chip.

15. The three-dimensional stacked optoelectronic packaging structure according to claim 12, wherein the heat dissipation cover plate is in direct or indirect contact with the electronic chips.

16. The three-dimensional stacked optoelectronic packaging structure according to claim 15, wherein a layer of thermal adhesive material or the encapsulation layer is positioned between the heat dissipation cover plate and the electronic chips.
